(19) United States
(12) Patent Application Publication
(10) Pub. No.: US 2019/0043721 A1
(43) Pub. Date: Feb. 7, 2019

(54) METHOD OF ETCHING MULTILAYERED FILM

(71) Applicant: Tokyo Electron Limited, Tokyo (JP)

(72) Inventor: Taku Gohira, Kurokawa-gun (JP)

(21) Appl. No.: 16/050,455

(22) Filed: Jul. 31, 2018

(30) Foreign Application Priority Data
Aug. 1, 2017 (JP) 2017-149186

(51) Int. Cl. H01L 21/033; H01L 21/311

(52) U.S. Cl. CPC H01L 21/0332; H01L 21/31116; H01L 21/31144

(57) ABSTRACT

A method of etching a multilayered film including multiple silicon oxide films and multiple silicon nitride films is provided. A mask containing carbon is provided on the multilayered film. The method includes performing a first plasma processing and performing a second plasma processing. In the performing of the first plasma processing and in the performing of the second plasma processing, plasma of a processing gas is generated within a chamber in a state that a temperature of an electrostatic chuck, on which a processing target object is placed, is set to be equal to or less than −15° C. The processing gas contains a hydrogen atom, a fluorine atom, a carbon atom and an oxygen atom, and also contains a sulfur-containing gas. A pressure of the chamber in the performing of the first plasma processing is set to be lower than that in the performing of the second plasma processing.

### CROSS-REFERENCE TO RELATED APPLICATION

This application claims the benefit of Japanese Patent Application No. 2017-149186 filed on Aug. 1, 2017, the entire disclosures of which are incorporated herein by reference.

### TECHNICAL FIELD

The embodiments described herein pertain generally to a method of etching a multilayered film.

### BACKGROUND

In the manufacture of a device such as a semiconductor device, plasma etching on an etching target film of a processing target object is performed. In the plasma etching, the processing target object is placed within a chamber of a plasma processing apparatus, and a processing gas is supplied into the chamber. The processing gas is excited, so that plasma is generated.

Patent Document 1 discloses a technique of performing plasma etching to form an opening having a high aspect ratio in a silicon oxide film as an etching target film. In the technique described in Patent Document 1, a mask made of amorphous carbon (amorphous carbon mask) is used. Further, in the technique described in Patent Document 1, the silicon oxide film is etched by generating plasma from a processing gas containing a hydrogen gas and a fluorine-containing gas such as a fluorocarbon gas or a hydrofluorocarbon gas.

Patent Document 1: Japanese Patent Laid-open Publication No. 2016-122774

### SUMMARY

In case of performing plasma etching to form an opening of a high aspect ratio in a multilayered film including a plurality of silicon oxide film and a plurality of silicon nitride film alternately stacked on top of each other, a carbon-containing mask such as the amorphous carbon mask may also be used. In the plasma etching of this multilayered film, a processing gas containing a carbon atom, a fluorine atom and a hydrogen atom, like the aforementioned processing gas, may also be used. During the plasma etching of this multilayered film, a deposit containing carbon is formed on the mask. Further, in this plasma etching, as the deposit or the mask as well as the deposit are etched by active species which react with them, the shape of multiple openings of the mask is decided. That is, the shape of the multiple openings of the mask during the plasma etching is determined by a residue of the initial mask or by the residue of the initial mask and the deposit.

The mask provided with the multiple openings has a region where the openings are formed at a high density (hereinafter, referred to as a “dense region”) and a region where the openings are formed at a low density (hereinafter, referred to as “sparse region”). In the plasma etching of the multilayered film with the aforementioned processing gas containing the carbon atom, the fluorine atom and the hydrogen atom, the shape of some openings of the mask may be deformed, so the shape of the multiple openings of the mask becomes non-uniform. This is deemed to be caused because there is a difference in the amounts of the active species respectively supplied to the sparse region and the dense region.

If the shape of the multiple openings of the mask becomes non-uniform, the multilayered film may not be uniformly etched under these multiple openings, and the shape of multiple openings formed in the multilayered film may also become non-uniform. As a result, verticality of these multiple openings is reduced. The verticality is high when the openings formed in the multilayered film are extended in parallel in a stacking direction of the multilayered film. Thus, it is required to improve the uniformity of the shape of the multiple openings of the mask during the etching of the multilayered film and, also, to improve the uniformity of the shape of the multiple openings formed in the multilayered film and the verticality of these multiple openings.

In one exemplary embodiment, there is provided a method of etching a multilayered film of a processing target object. The multilayered film includes multiple silicon oxide films and multiple silicon nitride films alternately stacked on top of each other. The processing target object includes a mask provided on the multilayered film. The mask contains carbon. The mask is provided with multiple openings. The method is performed in a state that the processing target object is placed on an electrostatic chuck within a chamber of a plasma processing apparatus. The method includes performing a first plasma processing to etch the multilayered film; and performing a second plasma processing to further etch the multilayered film after the performing of the first plasma processing. In the performing of the first plasma processing and in the performing of the second plasma processing, to etch the multilayered film, plasma of a processing gas is generated within the chamber in a state that a temperature of the electrostatic chuck is set to be equal to or less than −15° C. The processing gas contains a hydrogen atom, a fluorine atom and a carbon atom and also contains a sulfur-containing gas. A first pressure of the chamber in the performing of the first plasma processing is set to be lower than a second pressure of the chamber in the performing of the second plasma processing.

In the method, a deposit containing sulfur in the sulfur-containing gas is formed on the mask, and a shape of the multiple openings of the mask during the plasma etching is defined by the mask and the deposit thereon. A film of the deposit containing the sulfur is formed on the mask, having a relatively uniform film thickness. As a result, deformation of the multiple openings of the mask during the plasma etching is suppressed, so that uniformity of the shape of the multiple openings of the mask is improved.

If, however, the sulfur-containing gas is included in the processing gas, the mask may be etched relatively a lot. That is, selectivity would be lowered. In the method, to improve the selectivity, the temperature of the electrostatic chuck is set to be equal to or less than −15° C. If the temperature of the electrostatic chuck is set to be equal to or less than −15° C., an etching rate of the multilayered film is increased. Accordingly, the selectivity is improved.

If, meanwhile, the temperature of the electrostatic chuck is set to be equal to or less than −15° C., openings formed in the multilayered film may be bent with respect to a stacking direction of the multilayered film. To suppress this bending of the openings formed in the multilayered film, in the method, the first pressure of the chamber in the performing of the first plasma processing is set to be lower than the second pressure of the chamber in the performing of the second plasma processing. If the pressure of the chamber is low, though the openings extended in the stacking direction and having high verticality can be formed in the multilayered film, the selectivity would be lowered. Meanwhile, if the pressure of the chamber is high, the selectivity can be improved in the etching of the multilayered film. Thus, according to the method, it is possible to improve the selectivity and, also, to improve the uniformity and the verticality of the shape of the multiple openings formed in the multilayered film.

The performing of the first plasma processing is conducted until openings having an aspect ratio, which is equal to or larger than half of a required aspect ratio of the openings to be formed in the multilayered film and smaller than the required aspect ratio, are formed in the multilayered film.

The first pressure is equal to or lower than 2 Pascals (15 mTorr), and the second pressure is equal to or higher than 3.333 Pascals (25 mTorr).

The processing gas contains a hydrogen gas, a hydrofluorocarbon gas and an oxygen containing gas.

According to the exemplary embodiment as described above, it is possible to improve the uniformity of the shape of the multiple openings of the mask during the etching of the multilayered film and, also, to improve the uniformity of the shape of the multiple openings formed in the multilayered film and the verticality thereof.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a flowchart for describing a method of etching a multilayered film according to an exemplary embodiment;

FIG. 2 is a plan view illustrating an example of a processing target object to which the method shown in FIG. 1 is applied;

FIG. 3 is a plan view enlarging a part of a single pattern region of the processing target object shown in FIG. 2;

FIG. 4A is an enlarged plan view of a part A of FIG. 3 and FIG. 4B is an enlarged cross sectional view of the processing target object of the part A of FIG. 3;

FIG. 5 is a diagram schematically illustrating a plasma processing apparatus which can be used in performing the method shown in FIG. 1;

FIG. 6A is a plan view illustrating a partial region of a mask during a plasma etching using a processing gas which does not contain a sulfur-containing gas, and FIG. 6B is a cross sectional view of the processing target object during the plasma etching using the processing gas which does not contain the sulfur-containing gas;

FIG. 7A is a plan view illustrating the partial region of the mask during the plasma etching using a processing gas which contains a sulfur-containing gas, and FIG. 7B is a cross sectional view of the processing target object during the plasma etching using the processing gas which contains the sulfur-containing gas;

FIG. 8A is a graph showing a relationship between an aspect ratio and an area ratio obtained in a first experiment, and FIG. 8B is a graph showing a relationship between the aspect ratio and a flattening obtained in the first experiment;

FIG. 9 is a graph showing a relationship between the aspect ratio and an etching rate of the mask obtained in the first experiment;

FIG. 10A is a graph showing a relationship between a temperature of an electrostatic chuck and a selectivity obtained in a second experiment, and FIG. 10B is a graph showing a relationship between the temperature of the electrostatic chuck and 3σ of a change rate obtained in the second experiment;

FIG. 11 is a graph showing a relationship between a temperature of the electrostatic chuck and an average of an etching rate obtained in a third experiment;

FIG. 12A is a graph showing a relationship between a flow rate ratio of a SF₆ gas and an area ratio obtained in a fourth experiment, and FIG. 12B is a graph showing a relationship between the flow rate ratio of the SF₆ gas and a flattening of an opening at a central portion of a pattern region of the mask and a relationship between the flow rate ratio of the SF₆ gas and a flattening of an opening at an end portion of the pattern region of the mask obtained in the fourth experiment;

FIG. 13 is a graph showing a relationship between the flow rate ratio of the SF₆ gas and an average of a change rate and a relationship between the flow rate ratio of the SF₆ gas and 3σ of the change rate obtained in the fourth experiment; and

FIG. 14 is a graph showing a relationship between an aspect ratio and 3σ of a change rate obtained in a fifth experiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments will be described with reference to the accompanying drawings. In the various drawings, same or corresponding parts will be assigned same reference numerals.

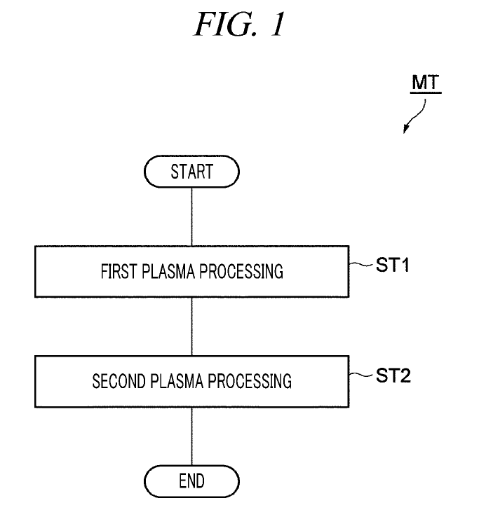

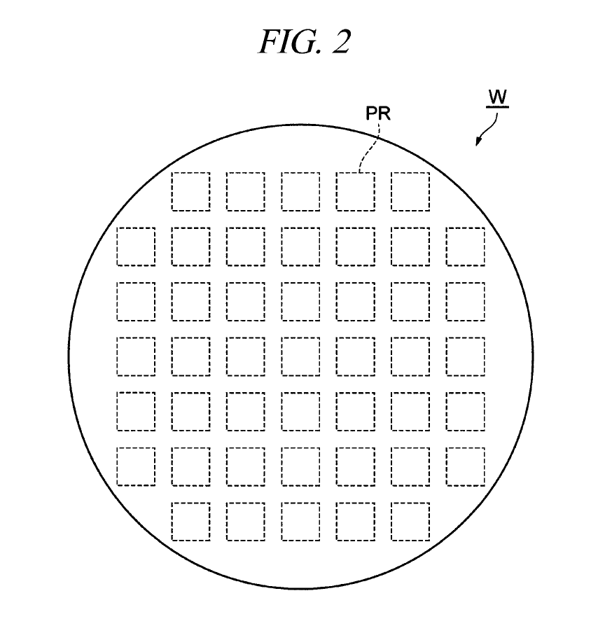

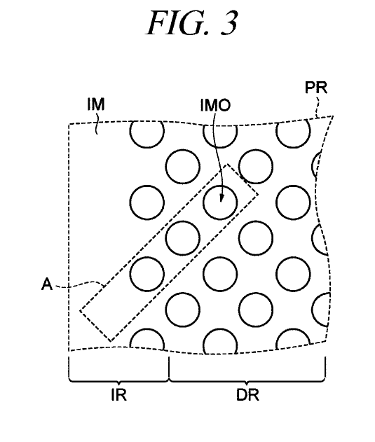

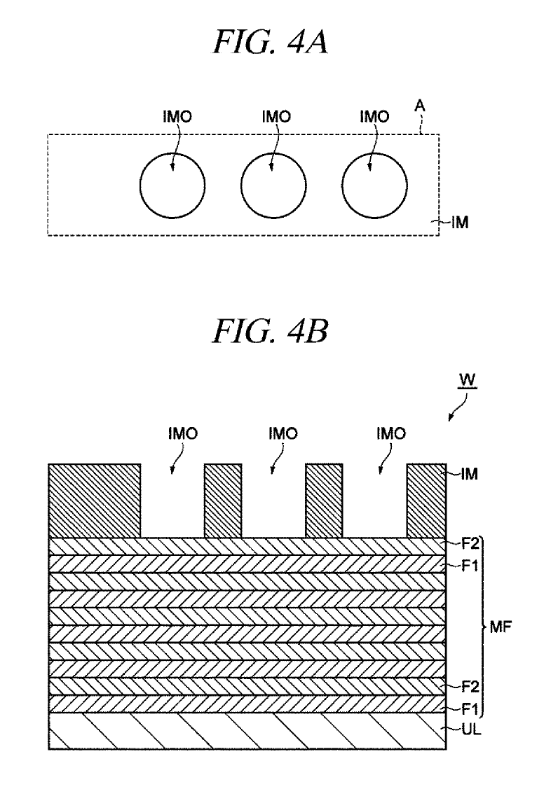

FIG. 1 is a flowchart for describing a method of etching a multilayered film according to an exemplary embodiment. A method MT shown in FIG. 1 includes a process ST1 of performing a first plasma processing to etch a multilayered film and a process ST2 of performing a second plasma processing to further etch the multilayered film. FIG. 2 is a plan view illustrating a processing target object to which the method shown in FIG. 1 is applied. FIG. 3 is a plan view enlarging a part of a single pattern region of the processing target object shown in FIG. 2. FIG. 4A is an enlarged plan view of a part A of FIG. 3, and FIG. 4B is an enlarged cross sectional view of the processing target object of the part A of FIG. 3.

As depicted in FIG. 2, an example processing target object W may have a substantially disk shape like a wafer. As shown in FIG. 4B, the processing target object W has a multilayered film MF and a mask IM. The multilayered film MF is provided on an underlying layer UL. The multilayered film MF includes multiple silicon oxide films F1 and multiple silicon nitride films F2. The multiple silicon oxide films F1 and the multiple silicon nitride films F2 are alternately stacked on top of each other. A number of the silicon oxide films F1 and a number of the silicon nitride films F2 of the multilayered film MF may be respectively set as required. Of all the films of the multilayered film MF, the bottommost film may be the silicon oxide film F1 or the silicon nitride film F2. Further, of all the films of the multilayered film MF, the topmost film may be the silicon oxide film F1 or the silicon nitride film F2. The mask IM is provided on the multilayered film MF. The mask IM contains carbon. The mask IM is made of, by way of example, but not limitation, amorphous carbon. The mask IM is provided with multiple openings IMO. Each of these multiple openings IMO may have, for example, a circular plane shape. Further, this mask IM is an initial mask having a state before the method MT is applied to the processing target object W. Each of the multiple openings IMO is an opening in the initial mask.

As depicted in FIG. 2, the processing target object W may have multiple pattern regions PR. In FIG. 2, a boundary of each of the multiple pattern regions PR is indicted by a dashed line. These multiple pattern regions PR are spaced apart from each other. Arrangement of the multiple pattern regions PR is not limited to the example shown in FIG. 2. As shown in FIG. 3, each of the multiple pattern regions PR is provided with a plurality of openings IMO. As depicted in FIG. 3, the mask IM provided with the multiple openings IMO has a region DR where the openings IMO are formed with high density and a region IR where the openings IMO are formed with low density.

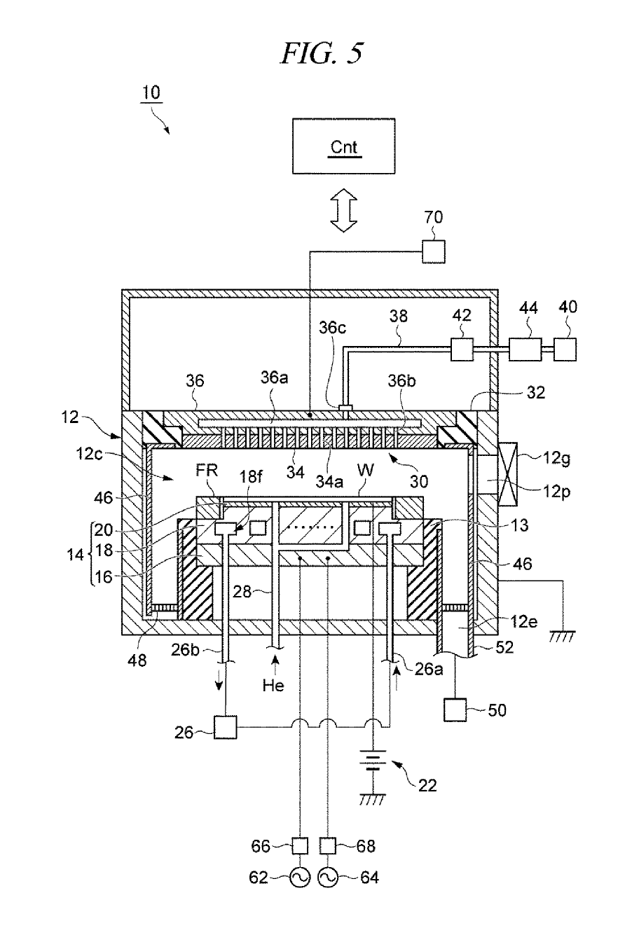

In the method MT, the aforementioned processes ST1 and ST2 are performed by using a plasma processing apparatus. FIG. 5 schematically illustrates the plasma processing apparatus that can be used in performing the method of FIG. 1. A plasma processing apparatus 10 shown in FIG. 5 is configured as a capacitively coupled plasma etching apparatus. The plasma processing apparatus 10 is equipped with a chamber main body 12. The chamber main body 12 has a substantially cylindrical shape. An internal space of the chamber main body 12 is configured as a chamber 12c. The chamber main body 12 is made of, by way of non-limiting example, aluminum. A processing for providing plasma resistance is performed on an inner wall surface of the chamber main body 12. By way of example, the inner wall surface of the chamber main body 12 is anodically oxidized. The chamber main body 12 is electrically grounded.

Further, a passage 12p is formed at a sidewall of the chamber main body 12. When the processing target object W is carried into or carried out of the chamber 12c, the processing target object W passes through the passage 12p. This passage 12p is opened/closed by a gate valve 12g.

A supporting member 13 is provided on a bottom portion of the chamber main body 12. The supporting member 13 is made of an insulating material and has a substantially cylindrical shape. The supporting member 13 is vertically extended from the bottom portion of the chamber main body 12 within the chamber 12c. The supporting member 13 is configured to support a stage 14. The stage 14 is provided within the chamber 12c.

The stage 14 is equipped with a lower electrode 18 and an electrostatic chuck 20. The stage 14 may be further equipped with an electrode plate 16. The electrode plate 16 is made of a conductor such as, but not limited to, aluminum and has a substantially disk shape. The lower electrode 18 is provided on the electrode plate 16. The lower electrode 18 is made of a conductor such as, but not limited to, aluminum and has a substantially disk shape. The lower electrode 18 is electrically connected with the electrode plate 16.

The electrostatic chuck 20 is provided on the lower electrode 18. The processing target object W is placed on a top surface of the electrostatic chuck 20. The electrostatic chuck 20 has a main body formed of a dielectric material. A film-shaped electrode is provided within the main body of the electrostatic chuck 20. The electrode of the electrostatic chuck 20 is connected to a DC power supply 22 via a switch. If a voltage is applied to the electrode of the electrostatic chuck 20 from the DC power supply 22, an electrostatic attracting force is generated between the electrostatic chuck 20 and the processing target object W. The processing target object W is attracted to and held by the electrostatic chuck 20 by the generated electrostatic attracting force.

A focus ring FR is provided on a peripheral portion of the lower electrode 18 to surround an edge of the processing target object W. The focus ring FR is configured to improve etching uniformity. The focus ring FR may be made of, but not limited to, silicon, silicon carbide or quartz.

A path 18f is provided within the lower electrode 18. A heat exchange medium (for example, a coolant) is supplied via a pipeline 26a into the path 18f from a chiller unit 26 provided at an outside of the chamber main body 12. The heat exchange medium supplied into the path 18f is returned back into the chiller unit 26 via a pipeline 26b. In the plasma processing apparatus 10, a temperature of the processing target object W placed on the electrostatic chuck 20 is adjusted by a heat exchange between the heat exchange medium and the lower electrode 18.

The plasma processing apparatus 10 is equipped with a gas supply line 28. Through the gas supply line 28, a heat transfer gas, e.g., a He gas from a heat transfer gas supply mechanism is supplied into a gap between the top surface of the electrostatic chuck 20 and a rear surface of the processing target object W.

The plasma processing apparatus 10 is further equipped with an upper electrode 30. The upper electrode 30 is provided above the stage 14. The upper electrode 30 is supported at an upper portion of the chamber main body 12 with a member 32 therebetween. The member 32 is made of a material having insulation property. The upper electrode 30 may include a ceiling plate 34 and a supporting body 36. A bottom surface of the ceiling plate 34 is a surface directly facing the chambers 12c, and it forms and confines the chamber 12c. The ceiling plate 34 may be made of a conductor or a semiconductor having low Joule heat. The ceiling plate 34 is provided with multiple gas discharge holes 34a. These gas discharge holes 34a are formed through the ceiling plate 34 in a plate thickness direction.

The supporting body 36 is configured to support the ceiling plate 34 in a detachable manner, and is made of a conductive material such as, but not limited to, aluminum. A gas diffusion space 36a is provided within the supporting body 36. Multiple gas holes 36b are extended downwards from the gas diffusion space 36a to communicate with the multiple gas discharge holes 34a, respectively. Further, the supporting body 36 is provided with a gas inlet port 36c through which a processing gas is introduced into the gas diffusion space 36a. A gas supply line 38 is connected to this gas inlet port 36c.

The gas supply line 38 is connected to a gas source group 40 via a valve group 42 and a flow rate controller group 44. The gas source group 40 includes a plurality of gas sources. The plurality of gas sources include sources of a plurality of gases constituting the processing gas used in the method MT. The valve group 42 includes a plurality of opening/closing valves. The flow rate controller group 44 includes a plurality of flow rate controllers. Each of the flow rate controllers may be implemented by a mass flow controller or a pressure control type flow rate controller. Each of the gas sources belonging to the gas source group 40 is connected to the gas supply line 38 via a corresponding valve belonging to the valve group 42 and a corresponding flow rate controller belonging to the flow rate controller group 44.

In the plasma processing apparatus 10, a shield 46 is provided along an inner wall of the chamber main body 12 in a detachable manner. Further, the shield 46 is also provided on an outer side surface of the supporting member 13. The shield 46 is configured to suppress an etching byproduct from adhering to the chamber main body 12. The shield 46 may be made of, by way of non-limiting example, an aluminum member coated with ceramic such as Y₂O₃.

A baffle plate 48 is provided between the supporting member 13 and the sidewall of the chamber main body 12. The baffle plate 48 may be made of, by way of example, an aluminum base member coated with ceramic such as Y₂O₃. The baffle plate 48 is provided with a plurality of through holes. A gas exhaust port 12e is provided at the bottom portion of the chamber main body 12 under the baffle plate 48. The gas exhaust port 12e is connected with a gas exhaust device 50 via a gas exhaust line 52. The gas exhaust device 50 has a pressure control valve and a vacuum pump such as a turbo molecular pump.

The plasma processing apparatus 10 is further equipped with a first high frequency power supply 62 and a second high frequency power supply 64. The first high frequency power supply 62 is configured to generate a first high frequency power for plasma generation. A frequency of the first high frequency power is in a range from 27 MHz to 100 MHz. The first high frequency power supply 62 is connected to the lower electrode 18 via a matching device 66 and the electrode plate 16. The matching device 66 is equipped with a circuit configured to match an output impedance of the first high frequency power supply 62 and an input impedance at a load side (lower electrode 18 side). Further, the first high frequency power supply 62 may be connected to the upper electrode 30 via the matching device 66.

The second high frequency power supply 64 is configured to generate a second high frequency power for ion attraction into the processing target object W. A frequency of the second high frequency power is lower than the frequency of the first high frequency power. The frequency of the second high frequency power falls within a range from 400 kHz to 13.56 MHz. The second high frequency power supply 64 is connected to the lower electrode 18 via a matching device 68 and the electrode plate 16. The matching device 68 is equipped with a circuit configured to match an output impedance of the second high frequency power supply 64 and the input impedance at the load side (lower electrode 18 side).

The plasma processing apparatus 10 may further include a DC power supply unit 70. The DC power supply unit 70 is connected to the upper electrode 30. The DC power supply unit 70 is configured to generate a negative DC voltage and apply the generated DC voltage to the upper electrode 30.

The plasma processing apparatus 10 may be further equipped with a control unit Cnt. The control unit Cnt may be implemented by a computer including a processor, a storage unit, an input device, a display device, and so forth. The control unit Cnt is configured to control individual components of the plasma processing apparatus 10. In the control unit Cnt, an operator can input commands through the input device to manage the plasma processing apparatus 10. Further, in the control unit Cnt, an operational status of the plasma processing apparatus 10 can be visually displayed on the display device. Further, the storage unit of the control unit Cnt stores therein recipe data and control programs for controlling various processings performed in the plasma processing apparatus 10 by the processor. As the processor of the control unit Cnt controls the individual components of the plasma processing apparatus 10 according to the recipe data by executing the control programs, the method MT is performed in the plasma processing apparatus 10.

Reference is made back to FIG. 1. Hereinafter, the method MT will be described for an example where the method MT is performed on the processing target object W shown in FIG. 2, FIG. 3, FIG. 4A and FIG. 4B by using the plasma processing apparatus 10. However, the target object to which the method MT is applied is not limited to the processing target object W. Further, the method MT may be performed by using a plasma processing apparatus other than the plasma processing apparatus 10.

The method MT is performed in a state that the processing target object W is placed on the electrostatic chuck 20 within the chamber 12c of the plasma processing apparatus 10. In the method MT, a first plasma processing is performed in a process ST1. In the method MT, a second plasma processing is performed in a subsequent process ST2.

In the first plasma processing of the process ST1 and the second plasma processing of the process ST2, plasma of the processing gas is generated within the chamber. The processing gas includes a hydrogen atom, a fluorine atom and a carbon atom, and, also, includes a sulfur-containing gas. To have the hydrogen atom, the processing gas may include one or more kinds of gases selected from a H₂ gas, a CₓH_{y} gas (hydrocarbon gas) and a CₓH_{y}F_{z} gas (hydrofluorocarbon gas). To have the fluorine atom, the processing gas may include a fluorine-containing gas. The fluorine-containing gas includes one or more kinds of gases selected from a HF gas, a NF₃ gas, a SF₆ gas, a WF₆ gas, a CₓF_{y} gas (fluorocarbon gas) and a CₓH_{y}F_{z} gas. Further, to have the carbon atom, the processing gas includes one or more kinds of gases selected from CₓH_{y} gas (hydrocarbon gas) and a CₓH_{y}F_{z} (hydrofluorocarbon gas). Here, x, y and z denote natural numbers. Further, as the sulfur-containing gas, the processing gas may include one or more kinds of gases selected from a H₂S gas, a COS gas, a CH₃SH gas, a SBr₂ gas, a S₂Br₂ gas, a SF₂ gas, a S₂F₂ gas, a SF₄ gas, a SF₆ gas, a S₂F₁₀ gas, a SCl₂ gas, a S₂Cl₂ gas and a S₃Cl₃ gas. Furthermore, the processing gas may further include a halogen-containing gas such as a HBr gas. In addition, the processing gas may further include an oxygen-containing gas such as an O₂ gas, a CO gas or a CO₂ gas. As an example, the processing gas may be a mixed gas including a hydrogen gas, a hydrofluorocarbon gas and a fluorine-containing gas. As a more specific example, the processing gas may be a mixed gas including a H₂ gas, a CH₂F₂ gas, a SF₆ gas and a HBr gas.

In the first plasma processing of the process ST1 and the second plasma processing of the process ST2, the temperature of the processing target object W is set to be equal to or lower than −15° C. The temperature of the processing target object W is adjusted by the temperature of the heat exchange medium supplied into the path 18f.

In the process ST1, a pressure of the chamber 12c is set to a first pressure, and in the process ST2, the pressure of the chamber 12c is set to a second pressure. The first pressure is lower than the second pressure. For example, the first pressure is equal to or lower than 2 Pa (Pascal), that is, 15 mTorr, and the second pressure is equal to or higher than 3.333 Pa (Pascal), that is, 25 mTorr.

In the exemplary embodiment, the process ST1 is performed until the openings having an aspect ratio, which is equal to or larger than half of a required aspect ratio of the openings OP to be formed in the multilayered film MF and smaller than the required aspect ratio, is formed in the multilayered film MF. Thereafter, the process ST2 is performed until the opening OP having the required aspect ratio is formed.

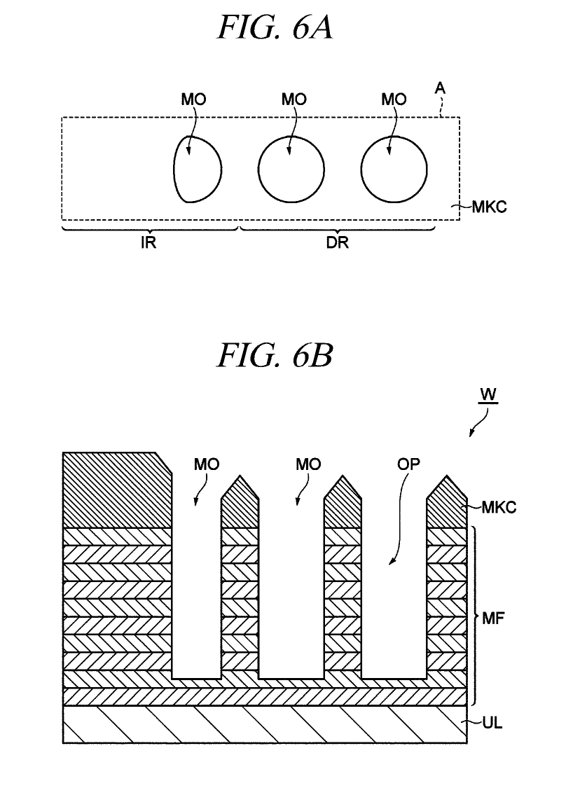

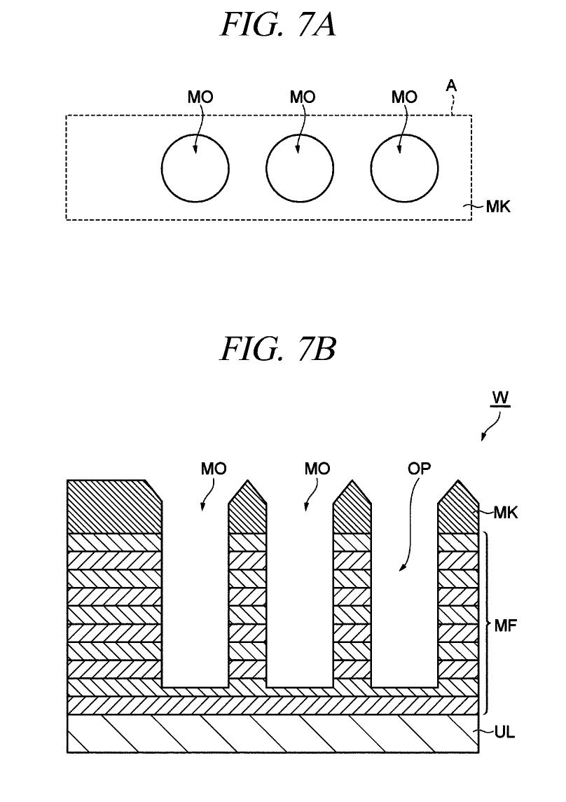

Now, reference is made to FIG. 6A, FIG. 6B, FIG. 7A and FIG. 7B. FIG. 6A is a plan view illustrating a partial region of the mask during a plasma etching with a processing gas which does not include a sulfur-containing gas, and FIG. 6B is a cross sectional view of the processing target object during the plasma etching with the processing gas which does not include the sulfur-containing gas. FIG. 7A is a plan view illustrating the partial region of the mask during the plasma etching with a processing gas including a sulfur-containing gas, and FIG. 7B is a cross sectional view of the processing target object during the plasma etching with the processing gas including the sulfur-containing gas.

In the etching of the multilayered film MF with plasma of the processing gas containing carbon, fluorine and hydrogen atoms and without containing the sulfur-containing gas, a deposit containing carbon (carbon-containing deposit) is formed on the mask. During the plasma etching, as the deposit or the mask as well as the deposit are etched by active species which react with them, the shape of the multiple openings MO of the mask MKC is decided. That is, the shape of the multiple openings MO of the mask MKC during the plasma etching is determined by a residue of the initial mask IM or by the residue of the initial mask IM and the deposit. Furthermore, the active species include oxygen generated during the etching of the multilayered film MF.

The amount of the oxygen generated during the etching of the multilayered film MF is large at the region DR where the openings MO are formed with the high density and is small at the region IR where the openings MO are formed with the low density. Accordingly, as depicted in FIG. 6A and FIG. 6B, some openings MO of the mask MKC are deformed. By way of example, plane shapes of several openings MO of the region IR may be deformed from the circular shape. As a result, the shape of the multiple openings MO of the mask MKC becomes non-uniform. If the shape of the multiple openings MO of the mask MKC is not uniform, the multilayered film MF may not be etched uniformly under these multiple openings MO, and, thus, the shape of the multiple openings OP formed in the multilayered film MF may also become non-uniform. Consequently, the verticality of the multiple openings OP may be lowered.

Meanwhile, in the method MT, a deposit containing sulfur in the sulfur-containing gas is formed on the mask, and the shape of the multiple openings MO of the mask MK during the plasma etching is defined by the mask and the deposit thereon. A film of the deposit containing the sulfur is formed on the mask, having a relatively uniform film thickness. As a result, according to the method MT, as shown in FIG. 7A and FIG. 7B, deformation of the multiple openings MO of the mask MK during the plasma etching is suppressed, so that the uniformity of the shape of the multiple openings MO of the mask MK is improved.

If, however, the sulfur-containing gas is included in the processing gas, the mask may be etched relatively a lot. That is, selectivity would be lowered. In the method MT, to improve the selectivity, the temperature of the electrostatic chuck 20 is set to be equal to or less than −15° C. If the temperature of the electrostatic chuck 20 is set to be equal to or less than −15° C., an etching rate of the multilayered film MF is increased. Accordingly, the selectivity is improved.

If, meanwhile, the temperature of the electrostatic chuck 20 is set to −15° C. or less, the openings formed in the multilayered film MF may be bent with respect to the stacking direction of the multilayered film MF. To suppress this bending of the openings formed in the multilayered film MF, in the method MT, the first pressure of the chamber 12c in the process ST1 is set to be lower than the second pressure of the chamber 12c in the process ST2. If the pressure of the chamber 12c is low, though the openings OP extended in the stacking direction and having high verticality can be formed in the multilayered film MF, the selectivity would be lowered. Meanwhile, if the pressure of the chamber 12c is high, the selectivity can be improved in the etching of the multilayered film MF. Thus, according to the method MT, it is possible to improve the selectivity and, also, to improve the uniformity and the verticality of the shape of the multiple openings OP formed in the multilayered film MF.

So far, the exemplary embodiment of the method MT has been described. However, the exemplary embodiment is not limiting, and various changes and modifications may be made. In the method MT, a plasma processing apparatus other than the capacitively coupled plasma processing apparatus can be used. By way of example, an inductively coupled plasma processing apparatus or a plasma processing apparatus configured to generate plasma by using a surface wave such as a microwave may be used for the method MT.

Now, various experiments conducted to evaluate the method MT will be explained. First, definitions of some evaluation values obtained in the experiments will be described. Further, in the experiments conducted to obtain the evaluation values, the opening of the initial mask, that is, the mask before the plasma etching is conducted has a circular plane shape.

In some experiments, an area ratio is calculated as the evaluation value. Here, the “area ratio” is a value obtained by dividing an area of the openings MO at an end portion of the pattern region PR of the mask after the plasma etching of the experiments by an area of the openings MO at a central portion of the pattern region PR of the mask after the plasma etching. As the area ratio becomes closer to 1, it means that the shape of the openings MO of the mask is uniform.

Further, in some experiments, a flattening is calculated. Here, the “flattening” is a value obtained by dividing a difference between a long diameter and a short diameter of the opening MO at the end portion of the pattern region PR of the mask after the plasma etching of the experiments by the corresponding long diameter. As the flattening becomes closer to zero (0), it implies that the deformation (distortion) of the opening of the mask at the end portion of the pattern region PR, that is, at the sparse region is smaller.

Furthermore, in some experiments, a change rate is calculated. Here, the change rate is defined by the following expression (1).

Change rate (%)=(P−Q)/P×100 (1)

In the expression (1), P denotes a distance between centers of two neighboring openings IMO in the initial mask. Q denotes a distance between centers of bottom portions of two neighboring openings OP formed in the multilayered film MF under the two neighboring openings IMO by the plasma etching. If an average of the change rate and a value of 3×(standard deviation of the change rate), that is, a value of 3σ of the change rate are small, the shape of openings OP formed in the multilayered film MF is uniform and the verticality of these openings OP is high.

In addition, in some experiments, a selectivity is calculated. The selectivity is defined as a value obtained by dividing an etching rate of the multilayered film by an etching rate of the mask. A higher value of the selectivity implies that it is possible to etch the multilayered film while suppressing the mask from being etched, that is, implies that the selectivity is high.

(First Experiment)

In the first experiment, the processing target object W as shown in FIG. 2, FIG. 3, FIG. 4A and FIG. 4B is prepared. The plasma etching of the multilayered film MF is performed by using the plasma processing apparatus 10, and a relationship between the aspect ratio of the multiple openings OP formed in the multilayered film MF and each of the area ratio, the flattening and the etching rate of the mask is calculated. In the first experiment, the plasma etching of the multilayered film MF is performed under two different conditions where a processing gas contains a H₂S gas at a flow rate ratio of 3.5% and where a processing gas does not contain the H₂S gas. Here, the flow rate ratio of the H₂S gas is a ratio of a flow rate of the H₂S gas to a total flow rate of the processing gas. Other conditions for the plasma etching in the first experiment are specified as follows.

<Conditions for Plasma Etching in First Experiment>
Processing gas: a mixed gas containing a H₂ gas, a CH₂F₂ gas, a H₂S gas and a HBr gas
Pressure of chamber 12c: 3.333 Pa (25 mTorr)
Temperature of electrostatic chuck 20: 0° C.
First high frequency power: 2.5 kW, 40 MHz, continuous wave
Second high frequency power: 7 kW, 0.4 MHz, continuous wave

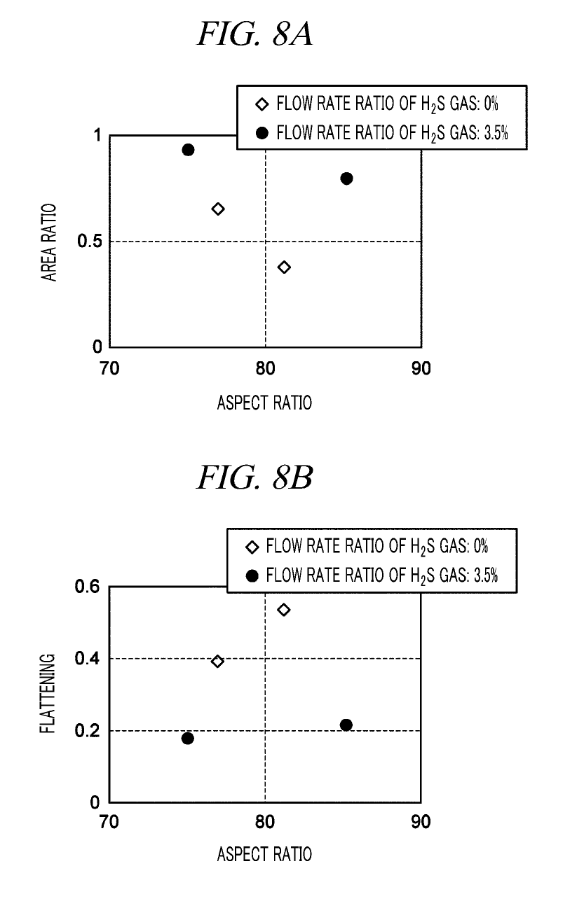

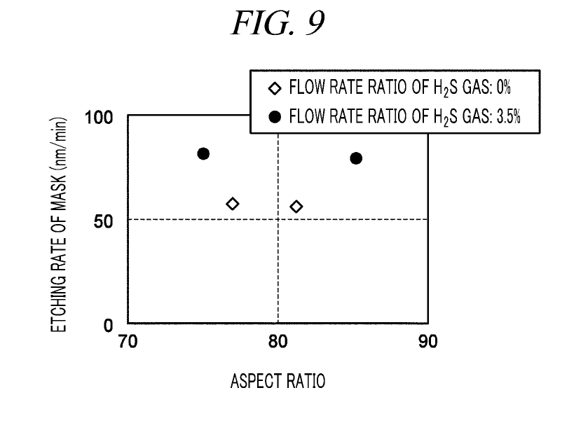

FIG. 8A is a graph showing a relationship between the aspect ratio and the area ratio obtained in the first experiment; FIG. 8B, a graph showing a relationship between the aspect ratio and the flattening obtained in the first experiment; and FIG. 9, a graph showing a relationship between the aspect ratio and the etching rate of the mask obtained in the first experiment. As depicted in FIG. 8A and FIG. 8B, in the plasma etching using the processing gas containing the H₂S gas, the area ratio is found to be close to 1 and the flattening is found to be small, as compared to the plasma etching using the processing gas not containing the H₂S gas. That is, it is found out that, by adding the H₂S gas as a kind of the sulfur-containing gas to the processing gas, the deformation of the openings of the mask at the end portion of the pattern region PR is suppressed and the shape of the multiple openings of the mask becomes uniform. As depicted in FIG. 9, in the plasma etching using the processing gas containing the H₂S gas, however, it is found out that the etching rate of the mask is higher than that in case of the plasma etching using the processing gas not containing the H₂S gas. That is, in the plasma etching using the processing gas containing the H₂S gas, the selectivity is lower than that in case of the plasma etching using the processing gas not containing the H₂S gas.

(Second Experiment)

In the second experiment, the same processing target object W as used in the first experiment is prepared. The plasma etching of the multilayered film MF is performed by using the plasma processing apparatus 10, and a relationship between the temperature of the electrostatic chuck 20 and each of the selectivity and 3σ of the change rate is calculated. Below, conditions for the plasma etching in the second experiment are specified. In the second experiment, the processing gas contains a SF₆ gas at a flow rate ratio of 3.5%.

<Conditions for Plasma Etching in Second Experiment>
Processing gas: a mixed gas containing a H₂ gas, a CH₂F₂ gas, a SF₆ gas and a HBr gas
Pressure of chamber 12c: 3.333 Pa (25 mTorr)
First high frequency power: 2.5 kW, 40 MHz, continuous wave
Second high frequency power: 7 kW, 0.4 MHz, continuous wave
Aspect ratio of the openings OP formed in the multilayered film MF: 80

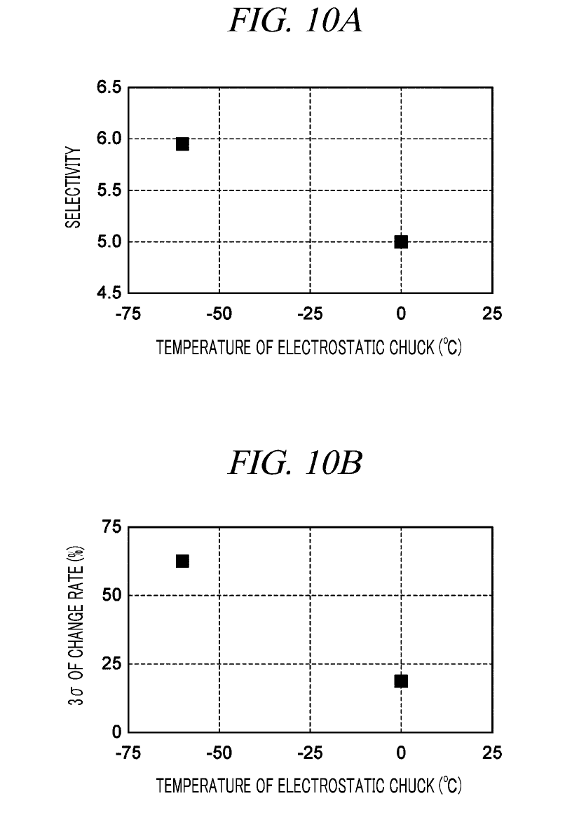

FIG. 10A is a graph showing a relationship between the temperature of the electrostatic chuck and the selectivity obtained in the second experiment, and FIG. 10B is a graph showing a relationship between the temperature of the electrostatic chuck and the 3σ of the change rate obtained in the second experiment. As depicted in FIG. 10A, if the temperature of the electrostatic chuck is decreased, the selectivity is increased. Accordingly, it is found out that the selectivity can be improved by setting the temperature of the electrostatic chuck to be low. Meanwhile, as can be seen from FIG. 10B, if the temperature of the electrostatic chuck is decreased, the 3σ of the change rate is increased. Accordingly, it is found out that the shape of the multiple openings OP formed in the multilayered film MF becomes non-uniform as the temperature of the electrostatic chuck is decreased.

(Third Experiment)

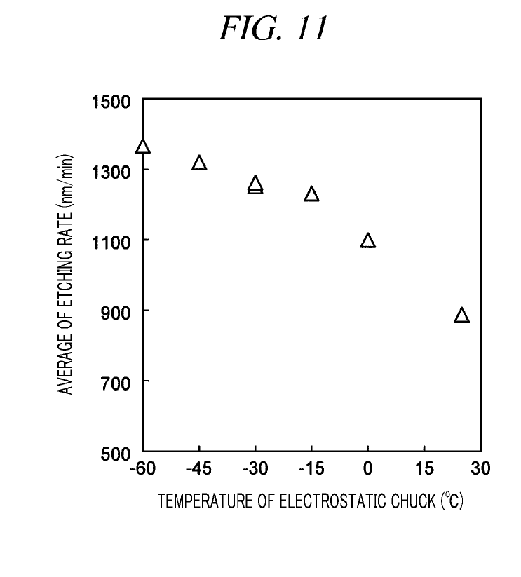

In the third experiment, the etching of the silicon oxide film and the silicon nitride film is performed under the same conditions as in the second experiment by using the plasma processing apparatus 10. In the third experiment, a relationship between the temperature of the electrostatic chuck 20 and an average of the etching rate is obtained. The average of the etching rate is an average of the etching rate of the silicon oxide film and the etching rate of the silicon nitride film. FIG. 11 is a graph showing the relationship between the temperature of the electrostatic chuck and the average of the etching rate obtained in the third experiment. As can be seen from FIG. 11, when the temperature of the electrostatic chuck is equal to or less than −15° C., a considerably high average of the etching rate is obtained. Accordingly, it is found out that, by setting the temperature of the electrostatic chuck to be equal to or less than −15° C., the etching rate of the multilayered film MF can be improved and thus the selectivity can be bettered.

(Fourth Experiment)

In the fourth experiment, a SF₆ gas is used as the sulfur-containing gas included in the processing gas. In the fourth experiment, the same processing target object W as used in the first experiment is prepared. The plasma etching of the multilayered film MF is performed by using the plasma processing apparatus 10, and a relationship between the flow rate ratio of the SF₆ gas and each of the area ratio, the flattening of the opening MO at the central portion of the pattern region PR of the mask, the flattening of the opening MO at the end portion of the pattern region PR of the mask, an average of the change rate and the 3σ of the change rate is obtained. Here, the flow rate ratio of the SF₆ gas is a ratio of the flow rate of the SF₆ gas to the total flow rate of the processing gas. Conditions for the plasma etching in the fourth experiment are specified as follows.

<Conditions for Plasma Etching in Fourth Experiment>
Processing gas: a mixed gas containing a H₂ gas, a CH₂F₂ gas, a HBr gas and a SF₆ gas
Pressure of chamber 12c: 3.333 Pa (25 mTorr)
Temperature of electrostatic chuck 20: −40° C.
First high frequency power: 2.5 kW, 40 MHz, continuous wave
Second high frequency power: 7 kW, 0.4 MHz, continuous wave
Aspect ratio of openings OP formed in the multilayered film MF: 90

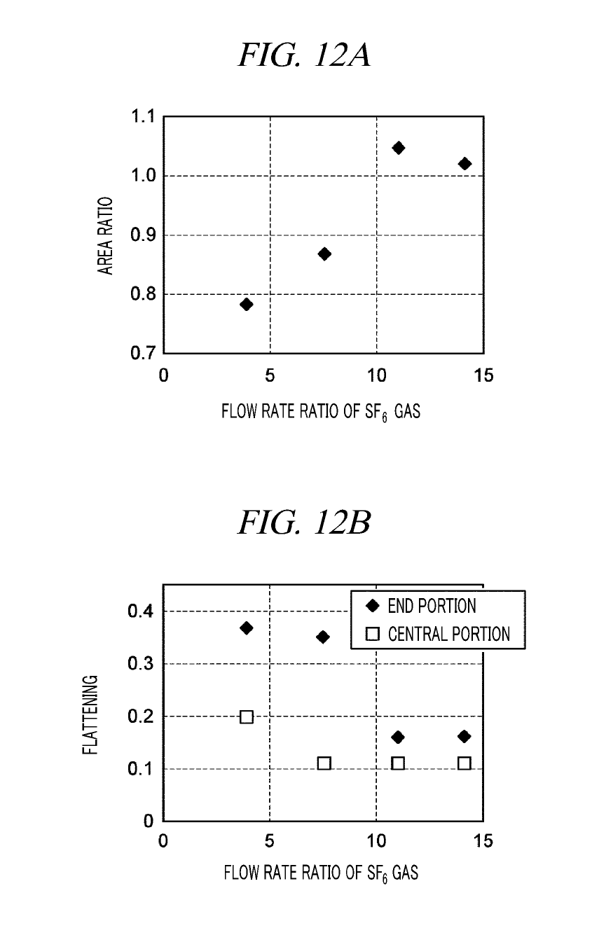

FIG. 12A is a graph showing a relationship between the flow rate ratio of the SF₆ gas and the area ratio obtained in the fourth experiment, and FIG. 12B is a graph showing a relationship between the flow rate ratio of the SF₆ gas and each of the flattening of the opening at the central portion of the pattern region of the mask and the flattening of the opening at the end portion of the pattern region of the mask obtained in the fourth experiment. Even if the SF₆ gas is used as the sulfur-containing gas instead of the H₂S gas, the area ratio is still close to 1 and the flattenings are still small, as shown in FIG. 12A and FIG. 12B. Accordingly, it is deemed that, by using any kind of sulfur-containing gas, the deformation of the openings of the mask is suppressed and the shape of the multiple openings of the mask is uniformed. Further, in case that the flow rate ratio of the SF₆ gas is equal to or larger than 10%, the deformation of the openings of the mask is further suppressed, and the shape of the multiple openings of the mask is further uniformed.

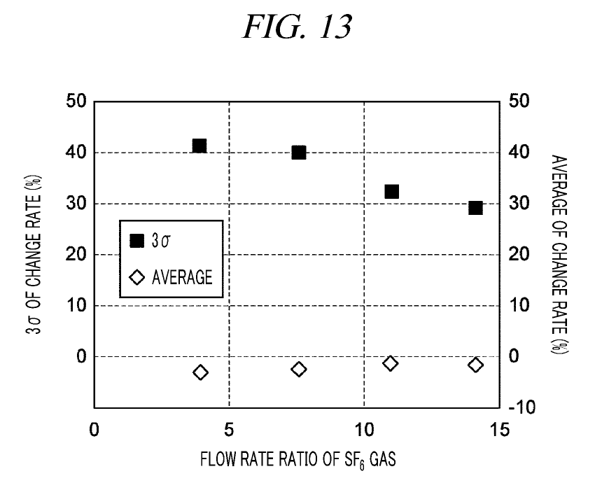

FIG. 13 is a graph showing a relationship between the flow rate ratio of the SF₆ gas and each of the average of the change rate and the 3σ of the change rate obtained in the fourth experiment. As shown in FIG. 13, the average of the change rate does not rely on the flow rate ratio of the SF₆ gas and is substantially zero. Further, the 3σ of the change rate is large without depending on the flow rate ratio of the SF₆ gas. Accordingly, under the conditions of the plasma etching of the fourth experiment, the shape of the multiple openings OP formed in the multilayered film MF is found to be non-uniform regardless of the flow rate ratio of the SF₆ gas. Further, the reason why the average of the change rate is small though the 3σ of the change rate is large is because non-uniformity is caused in the extension direction of the openings OP with respect to the stacking direction of the multilayered film MF and, thus, there exist the change rate having a positive value and the change rate having a negative value. If the shape of the multiple openings OP formed in the multilayered film MF is non-uniform and if the verticality of the multiple openings OP is low, the 3σ of the change rate is increased. Therefore, it can be understood from the result of the fourth experiment that both the uniformity of the shape of the multiple openings OP formed in the multilayered film MF and the verticality of the multiple openings OP can be used to evaluate only the 3σ of the change rate.

(Fifth Experiment)

In a fifth experiment, the same processing target object W as used in the first experiment is prepared. The plasma etching of the multilayered film MF is performed by using the plasma processing apparatus 10, and a relationship between the aspect ratio of the openings OP formed in the multilayered film MF and the 3σ of the change rate is obtained. Conditions for the plasma etching in the fifth experiment are specified as follows. Further, in the fifth experiment, the flow rate ratio of the SF₆ gas is 14%. Further, as specified below, in the fifth experiment, the pressure of the chamber 12c is set to be the following conditions 5A, 5B, 5C and 5D, respectively.

<Conditions for Plasma Etching in Fifth Experiment>
Processing gas: a mixed gas containing a H₂ gas, a CH₂F₂ gas, a SF₆ gas and a HBr gas
Pressure of chamber 12c:
   Condition 5A: constant at 15 mTorr (2 Pa)
   Condition 5B: constant at 25 mTorr (3.333 Pa)
   Condition 5C:
      Until aspect ratio reaches 40:15 mTorr (2 Pa)
      After aspect ratio reaches 40:25 mTorr (3.333 Pa)
   Condition 5D:
      Until aspect ratio reaches 60:15 mTorr (2 Pa)
      After aspect ratio reaches 60:25 mTorr (3.333 Pa)
Temperature of electrostatic chuck 20: −40° C.
First high frequency power: 2.5 kW, 40 MHz, continuous wave
Second high frequency power: 7 kW, 0.4 MHz, continuous wave

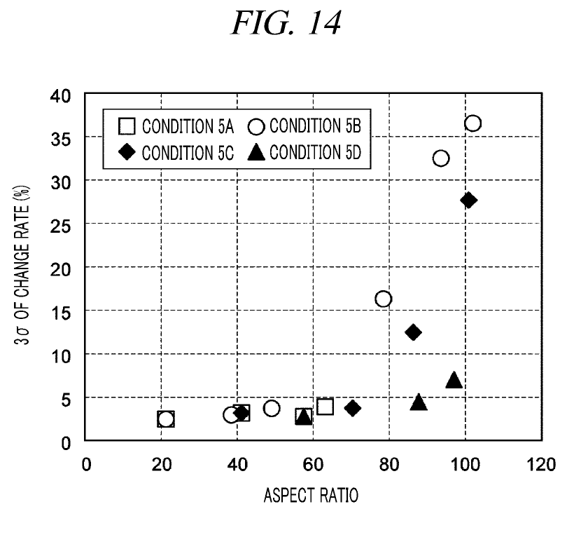

FIG. 14 is a graph showing a relationship between the aspect ratio and the 3σ of the change rate obtained in the fifth experiment. As shown in FIG. 14, in the plasma etching under the condition 5A, that is, in the plasma etching where the pressure of the chamber 12c is maintained to be 15 mTorr (2 Pa) without being varied, though the 3σ of the change rate is low, the selectivity is low, so that the mask MK cannot be maintained and the multiple openings having a high aspect ratio cannot be formed in the multilayered film MF. In the plasma etching under the condition 5B, that is, in the plasma etching where the pressure of the chamber 12c is maintained to be 25 mTorr (3.333 Pa) without being varied, the 3σ of the change rate is found to be increased greatly in case that the aspect ratio of the multiple openings OP formed in the multilayered film MF is larger than 50.

Meanwhile, in the plasma etching under each of the conditions 5C and 5D, that is, in the plasma etching where the first plasma processing is performed by setting the pressure of the chamber 12c to be relatively low and then the second plasma processing is performed by setting the pressure of the chamber 12c to be relatively high, it is found out that the openings having a higher aspect ratio than that in the plasma etching under the condition 5A can be formed in the multilayered film MF. Further, in the plasma etching under each of the conditions 5C and 5D, the multiple openings OP having a smaller 3σ of the change rate than that in the plasma etching under the condition 5B can be formed in the multilayered film MF. Further, in the plasma etching under the condition 5D, the multiple openings having a higher aspect ratio with a small 3σ of the change rate can be formed, as compared to the plasma etching under the condition 5C. In view of this, it is deemed that by performing the plasma processing at the low pressure (first plasma processing) until the openings having an aspect ratio equal to or larger than half of a required aspect ratio of the openings OP to be formed in the multilayered film MF and smaller than the required aspect ratio are formed in the multilayered film MF and then by performing the plasma processing at the high pressure (second plasma processing), the selectivity can be improved and, also, the uniformity and the verticality of the multiple openings OP formed in the multilayered film MF can be improved.

From the foregoing, it will be appreciated that the exemplary embodiment of the present disclosure has been described herein for purposes of illustration, and that various modifications may be made without departing from the scope and spirit of the present disclosure. Accordingly, the embodiment disclosed herein is not intended to be limiting. The scope of the inventive concept is defined by the following claims and their equivalents rather than by the detailed description of the exemplary embodiment. It shall be understood that all modifications and embodiments conceived from the meaning and scope of the claims and their equivalents are included in the scope of the inventive concept.

We claim:

1. A method of etching a multilayered film of a processing target object,
wherein the multilayered film comprises multiple silicon oxide films and multiple silicon nitride films alternately stacked on top of each other,
the processing target object includes a mask which is provided on the multilayered film and which contains carbon,
the mask is provided with multiple openings,
wherein the method is performed in a state that the processing target object is placed on an electrostatic chuck within a chamber of a plasma processing apparatus, and the method comprises:
performing a first plasma processing to etch the multilayered film; and
performing a second plasma processing to further etch the multilayered film after the performing of the first plasma processing,
wherein, in the performing of the first plasma processing and in the performing of the second plasma processing, to etch the multilayered film, plasma of a processing gas is generated within the chamber in a state that a temperature of the electrostatic chuck is set to be equal to or less than −15° C.,
the processing gas contains a hydrogen atom, a fluorine atom and a carbon atom and also contains a sulfur-containing gas, and
a first pressure of the chamber in the performing of the first plasma processing is set to be lower than a second pressure of the chamber in the performing of the second plasma processing.

2. The method of claim 1,
wherein the performing of the first plasma processing is conducted until openings having an aspect ratio, which is equal to or larger than half of a required aspect ratio of the openings to be formed in the multilayered film and smaller than the required aspect ratio, are formed in the multilayered film.

3. The method of claim 1,
wherein the first pressure is equal to or lower than 2 Pascals, and the second pressure is equal to or higher than 3.333 Pascals.

4. The method of claim 1,
wherein the processing gas contains a hydrogen gas and a hydrofluorocarbon gas.

5. The method of claim 1,
wherein the processing gas contains a hydrogen bromide.

6. The method of claim 2,
wherein the first pressure is equal to or lower than 2 Pascals, and the second pressure is equal to or higher than 3.333 Pascals.

7. The method of claim 6,
wherein the processing gas contains a hydrogen gas and a hydrofluorocarbon gas.

8. The method of claim 7,
wherein the processing gas contains a hydrogen bromide.
